(19) United States
(12) Patent Application Publication
(10) Pub. No.: US 2025/0254874 A1
(43) Pub. Date: Aug. 7, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Jae Hyun HAN, Gyeonggi-do (KR)

(21) Appl. No.: 18/663,094

(22) Filed: May 14, 2024

(30) Foreign Application Priority Data
Feb. 6, 2024 (KR) 10-2024-0018091

(51) Int. Cl. H10B 43/27; H10B 41/27

(52) U.S. Cl. CPC H10B 43/27; H10B 41/27

(57) ABSTRACT

A semiconductor device may include a gate structure including stacked conductive layers and insulating regions disposed between the conductive layers; a channel layer extending through the gate structure; data storage patterns surrounding the channel layer and disposed between the channel layer and the conductive layers, respectively; oxidation patterns surrounding the channel layer and disposed between the channel layer and the insulating regions, respectively; and a blocking layer surrounding the data storage patterns and the oxidation patterns and including concave portions disposed to correspond to the insulating regions.

### CROSS-REFERENCE TO RELATED APPLICATION

This application claims priority under 35 U.S.C. § 119 to Korean Patent Application No. 10-2024-0018091 filed on Feb. 6, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as improvements in the degree of integration of a semiconductor device for forming memory cells in a single layer on a substrate reach a limit, a three-dimensional semiconductor device for stacking memory cells on a substrate has been proposed. Furthermore, to improve the operational reliability of such a semiconductor device, various structures and manufacturing methods have been developed.

### SUMMARY

In an embodiment of the present disclosure, a semiconductor device may include a gate structure including stacked conductive layers and insulating regions disposed between the conductive layers; a channel layer extending through the gate structure; data storage patterns surrounding the channel layer and disposed between the channel layer and the conductive layers, respectively; oxidation patterns surrounding the channel layer and disposed between the channel layer and the insulating regions, respectively; and a blocking layer surrounding the data storage patterns and the oxidation patterns and including concave portions disposed to correspond to the insulating regions.

In an embodiment of the present disclosure, a semiconductor device may include: a gate structure including stacked gate lines; a channel layer extending through the gate structure; a tunneling structure surrounding the channel layer and including protrusion portions disposed between the gate lines; data storage patterns surrounding the tunneling structure and disposed between the protrusion portions, respectively; a blocking layer surrounding the data storage patterns and the tunneling structure; and a sealing layer extending through the gate structure and defining air gaps disposed between the gate lines, wherein each of the air gaps may protrude into the blocking layer and the sealing layer.

In an embodiment of the present disclosure, a manufacturing method of a semiconductor device may include forming a stack including first material layers and second material layers that are alternately stacked; forming a first opening extending through the stack; forming a blocking layer within the first opening; forming a data storage layer within the blocking layer; forming a slit extending through the stack; forming second openings by etching the second material layers through the slit, the second openings exposing the blocking layer; forming concave portions on a surface of the blocking layer by etching the blocking layer exposed through the second openings; and oxidizing the data storage layer through the concave portions of the blocking layer.

### BRIEF DESCRIPTION OF THE DRAWINGS

FIGS. 1A to 1C are diagrams illustrating the structure of a semiconductor device in accordance with an embodiment of the present disclosure.

FIG. 2 is a diagram illustrating the structure of a semiconductor device in accordance with an embodiment of the present disclosure.

FIG. 3 is a diagram illustrating the structure of a semiconductor device in accordance with an embodiment of the present disclosure.

FIGS. 4A to 4E are diagrams for describing a manufacturing method of a semiconductor device in accordance with an embodiment of the present disclosure.

FIGS. 5A to 5C are diagrams for describing a manufacturing method of a semiconductor device in accordance with an embodiment of the present disclosure.

### DETAILED DESCRIPTION

Various embodiments of the present disclosure are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical scope of the present disclosure will be described with reference to the accompanying drawings.

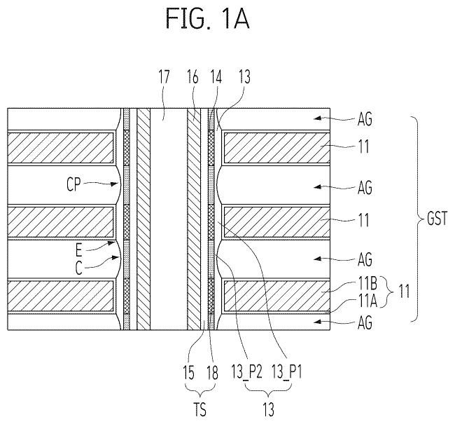

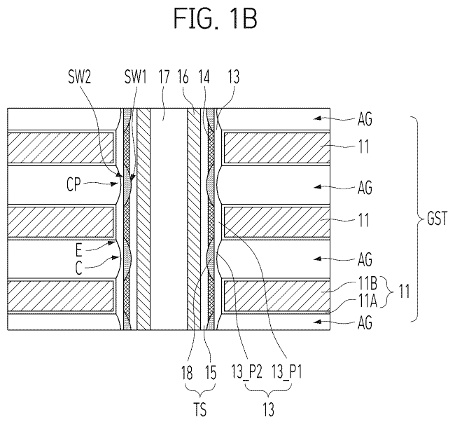

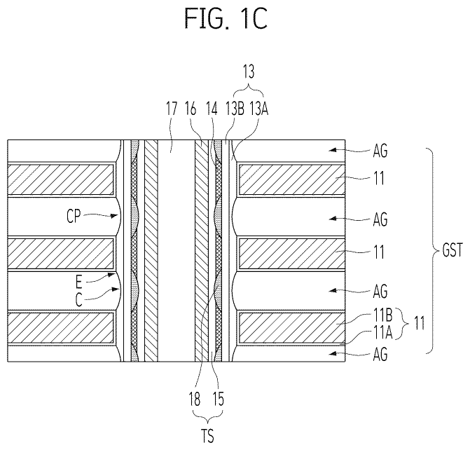

FIGS. 1A to 1C are diagrams illustrating the structure of a semiconductor device in accordance with an embodiment of the present disclosure.

Referring to FIG. 1A, the semiconductor device may include a gate structure GST, a channel layer 16, data storage patterns 14, and a blocking layer 13. The semiconductor device may further include at least one of a tunneling structure TS and an insulating core 17.

The gate structure GST may include stacked conductive layers 11 and insulating regions disposed between the conductive layers 11. For example, the insulating region may include an air gap AG. Along the stacking direction, the conductive layers 11 and the air gaps AG may be alternately disposed. For example, the conductive layers 11 may be gate lines such as select lines or word lines. The conductive layers 11 may include a conductive material such as polysilicon or metal. For example, the conductive layer 11 may include a barrier layer 11A and a metal layer 11B disposed within the barrier layer 11A. The barrier layer 11A may enclose the metal layer 11B defining an outer boundary for the conductive layer 11. The barrier layer 11A may include, for example, metal nitride, and the metal layer 11B may include, for example, tungsten (W), molybdenum (Mo), or the like. The air gaps AG may be empty spaces between the conductive layers 11 and may electrically insulate the conductive layers 11 from each other.

The channel layer 16 may extend through the gate structure GST. The channel layer 16 may extend through the entire gate structure GST, i.e., from a front surface to a back surface of the gate structure GST. The front and back surfaces of the gate structure GST may also be referred to as a top surface and bottom surface of the gate structure GST, respectively. The channel layer 16 may include, for example, a semiconductor material such as silicon or germanium. The insulating core 17 may be disposed within the channel layer 16 and may include an insulating material such as, for example, an oxide or a nitride, and may include a void therein.

The tunneling structure TS may surround the channel layer 16, and may include protrusion portions (please refer to the oxidation patterns 18) disposed between the conductive layers 11. The protrusion portions may be disposed between the data storage patterns 14 in a vertical direction. For example, the tunneling structure TS may include a tunneling layer 15 and oxidation patterns 18. The tunneling layer 15 may surround a sidewall of the channel layer 16. The tunneling layer 15 may be disposed between the channel layer 16 and the conductive layers 11 and between the channel layer 16 and the air gaps AG. The oxidation patterns 18 may protrude from the tunneling layer 15 toward the air gaps AG. The oxidation patterns 18 may be disposed between the channel layer 16 and the air gaps AG, respectively. The oxidation patterns 18 may be disposed between the data storage patterns 14, respectively, and may separate the data storage patterns 14 from each other.

The oxidation patterns 18 may be formed by oxidizing a data storage layer. For example, the tunneling layer 15 may be an oxide layer formed through a deposition process, and the oxidation patterns 18 may each be an oxide layer formed through an oxidation process. An interface may exist or might not exist between the oxidation patterns 18 and the tunneling layer 15.

The data storage patterns 14 may surround a portion of the tunneling structure TS, and may be disposed between the protrusion portions of the tunneling structure TS, respectively. For example, the data storage patterns 14 may surround the channel layer 16 with the tunneling layer 15 interposed therebetween. The data storage patterns 14 may be disposed between the channel layer 16 and the conductive layers 11, and may be separated from each other by the oxidation patterns 18. The data storage patterns 14 may each include a floating gate, polysilicon, a charge trap material, nitride, a variable resistance material, or the like.

The blocking layer 13 may surround the data storage patterns 14 and the oxidation patterns 18. The blocking layer 13 may have a shape which extends continuously along the sidewall of the channel layer 16. The blocking layer 13 may be disposed between the data storage patterns 14 and the conductive layers 11, and also between the oxidation patterns 18 and the air gaps AG.

The blocking layer 13 may have different thicknesses depending on regions. The blocking layer 13 may include first portions 13_P1 surrounding the data storage patterns 14 and second portions 13_P2 surrounding the oxidation patterns 18. The first and second portions 13_P1 and 13_P2 may have different thicknesses. The second portions 13_P2 may have a smaller thickness than the first portions 13_P1. The air gaps AG may protrude toward the blocking layer 13, and as the air gaps AG protrude, the second portions 13_P2 may have smaller thickness than the first portions 13_P1.

The blocking layer 13 may include concave portions CP. The concave portions CP may be disposed on an outer wall of the blocking layer 13, and may be disposed to correspond to the air gaps AG. The concave portion CP may be disposed in the second portion 13_P2. Each concave portion CP may include a center C and an edge E, and the blocking layer 13 may have a smaller thickness at the center C than at the edge E. Each of the concave portions CP may have a surface with a round shape, and the surface with the round shape may be exposed through the air gap AG.

Referring to FIG. 1B, each of the oxidation patterns 18 may include a first sidewall SW1 facing the tunneling layer 15 and a second sidewall SW2 facing the blocking layer 13. The first sidewall SW1 may include a curved surface. In a cross section, e.g., as shown in FIG. 1B, the second sidewall SW2 may be flat. The oxidation patterns 18 may protrude into the tunneling layer 15. The data storage patterns 14 may include sidewalls facing the oxidation patterns 18, and the sidewalls may include curved surfaces. In a cross section, e.g., as shown in FIG. 1B, the data storage pattern 14 may have a trapezoidal shape with each of the bases of the trapezoid being oriented vertically (i.e., in the stacking direction).

The blocking layer 13 may include a high-k material such as, for example, hafnium oxide or aluminum oxide. When the blocking layer 13 includes a low-k material, a sufficient bias might not be applied to the tunneling layer 15 due to gate coupling ratio. In contrast, when the blocking layer 13 includes the high-k material, a bias applied to the tunneling layer 15 may be increased, and an operation of a memory cell may be improved.

Referring to FIG. 1C, the blocking layer 13 of the semiconductor device may be a multilayer. The blocking layer 13 may include a first blocking layer 13A and a second blocking layer 13B. The second blocking layer 13B may surround the data storage patterns 14 and the oxidation patterns 18. The first blocking layer 13A may surround the second blocking layer 13B. The second blocking layer 13B may be disposed between the oxidation patterns 18 and the first blocking layer 13A and between the data storage patterns 14 and the first blocking layer 13A. The second blocking layer 13B may have a thickness of 5 nm or less, e.g., of 5 nm to 1 nm, or 5 nm to 0.5 nm.

The first blocking layer 13A and the second blocking layer 13B may include materials having different dielectric constants. For example, the first blocking layer 13A may include a material having a higher dielectric constant than the second blocking layer 13B. The first blocking layer 13A may include a high-k material such as, for example, hafnium oxide or aluminum oxide, and the second blocking layer 13B may include a low-k material such as, for example, silicon oxide or silicon nitride. Accordingly, even though a leakage current increases due to the first blocking layer 13A including the high-k material, the leakage current may increase to a lesser degree by adding the second blocking layer 13B.

According to the structure described above, memory cells or select transistors may be disposed in regions where the channel layer 16 and the conductive layers 11 intersect each other. The data storage patterns 14 may be separated from each other by the oxidation patterns 18, and the memory cells may include the data storage patterns 14, respectively. Accordingly, data retention characteristics of the semiconductor device may be improved.

The air gaps AG may be disposed between the stacked conductive layers 11, and may reduce capacitance between the stacked conductive layers 11. Because the blocking layer 13 includes the concave portion CP, capacitance between the conductive layers 11 and the channel layer 16 may be reduced. Accordingly, an RC delay of the semiconductor device may be improved, and a program speed may be improved.

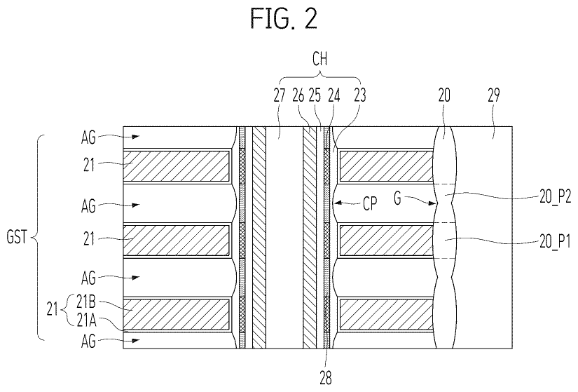

FIG. 2 is a diagram illustrating the structure of a semiconductor device in accordance with an embodiment of the present disclosure. Hereinafter, any description made earlier may not be repeated.

Referring to FIG. 2, the semiconductor device may include a gate structure GST and a channel structure CH. The semiconductor device may further include at least one of a sealing layer 20 and a source contact structure 29.

The gate structure GST may include conductive layers 21 and air gaps AG. Each of the conductive layers 21 may include a barrier layer 21A and a metal layer 21B. The channel structure CH may extend through the gate structure GST. The channel structure CH may include a channel layer 26, and may further include at least one of a blocking layer 23, data storage patterns 24, a tunneling layer 25, oxidation patterns 28, and an insulating core 27. The blocking layer 23 may include concave portions CP.

The source contact structure 29 may extend through the gate structure GST. For example, a source structure may be disposed below the gate structure GST, and the channel structure CH may extend into the source structure through the gate structure GST. The source contact structure 29 may penetrate through the gate structure GST, and may be electrically connected to the source structure. For reference, it is also possible for the semiconductor device to include a gap fill layer instead of the source contact structure 29. The gap fill layer may include an insulating material, a semiconductor material, or the like.

The sealing layer 20 may surround a sidewall of the source contact structure 29. The sealing layer 20 may include first portions 20_P1 and second portions 20_P2 alternating along the direction of stacking. The first portions 20_P1 may be disposed between the source contact structure 29 and the conductive layers 21. The second portions 20_P2 may be disposed between the source contact structure 29 and the air gaps AG. The second portions 20_P2 may have a smaller thickness than the first portions 20_P1. The air gaps AG may protrude into the sealing layer 20, and each of the second portions 20_P2 may include a groove G. The grooves G may be disposed to correspond to the air gaps AG, i.e., one groove G is formed next to each air gap AG. The sealing layer 20 may be an oxide layer formed by a chemical vapor deposition (CVD) method. The sealing layer 20 may be formed by depositing a sealing material in a manner in which step coverage is poor. The air gaps AG disposed between the conductive layers 21 may be defined by the blocking layer 23 and the sealing layer 20. The air gap AG may protrude into the blocking layer 23 and the sealing layer 20.

According to the structure described above, capacitance between the conductive layers 21 may be reduced through the air gap AG. In addition, capacitance between the channel layer 26 and the conductive layers 21 may be reduced through the concave portion CP. Accordingly, an RC delay of the semiconductor device may be improved, and a program operation speed may be improved.

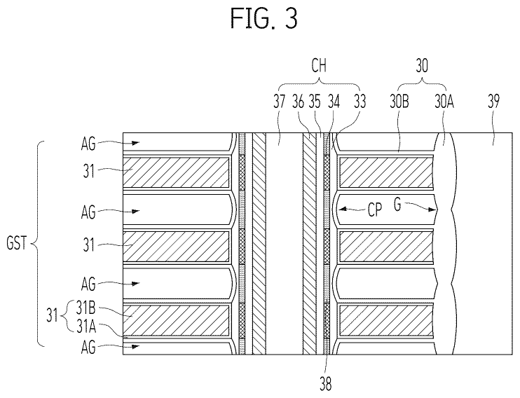

FIG. 3 is a diagram illustrating the structure of a semiconductor device in accordance with an embodiment of the present disclosure.

Hereinafter, any description made earlier may not be repeated.

Referring to FIG. 3, the semiconductor device may include a gate structure GST and a channel structure CH. The semiconductor device may further include at least one of a sealing layer 30 and a source contact structure 39.

The gate structure GST may include conductive layers 31 and air gaps AG. Each of the conductive layers 31 may include a barrier layer 31A and a metal layer 31B. The channel structure CH may extend through the gate structure GST. The channel structure CH may include a channel layer 36, and may further include at least one of a blocking layer 33, data storage patterns 34, a tunneling layer 35, oxidation patterns 38, and an insulating core 37. The blocking layer 33 may include concave portions CP.

The sealing layer 30 may include a penetration portion 30A and extension portions 30B. The penetration portion 30A may extend through the gate structure GST. The penetration portion 30A may include grooves G on an inner wall and/or an outer wall thereof. The extension portions 30B may protrude from the penetration portion 30A, and may extend into the gate structure GST along sidewalls of the conductive layers 21. The extension portions 30B may extend along the concave portions CP of the blocking layer 33, and the air gaps AG may be disposed within the extension portions 30B, respectively. Depending on step coverage of a deposition process of forming the sealing layer 30, the sealing layer 30 may include or might not include the extension portions 30B. In addition, depending on the step coverage, a thickness of the extension portion 30B may be adjusted to be great or small.

According to the structure described above, the air gaps AG and the extension portions 30B may be disposed between the stacked conductive layers 31. Accordingly, capacitance between the stacked conductive layers 31 may be reduced by the air gap AG. The extension portions 30B are disposed between the conductive layers 31, and accordingly, the capacitance between the conductive layers 31 may be reduced to a lesser degree, but a magnitude of a bias applied to the tunneling layer 35 may be increased by the extension portions 30B. Accordingly, it is possible to adjust whether or not to form the extension portions 30B and the thickness of the extension portions 30B in consideration of a change in capacitance depending on the air gap AG and the extension portion 30B.

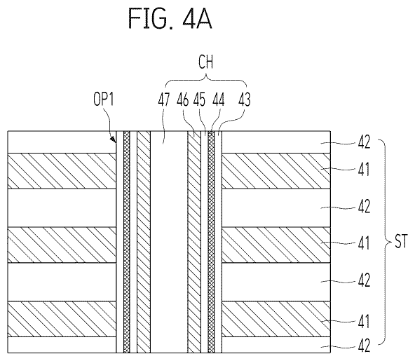

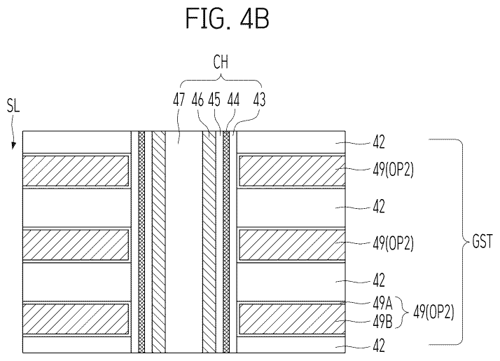

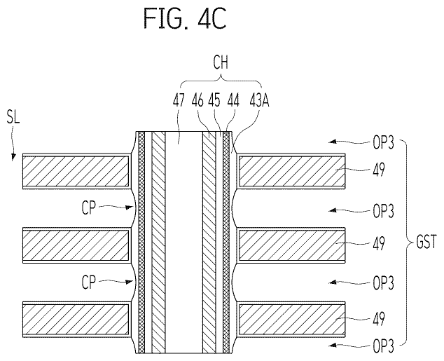

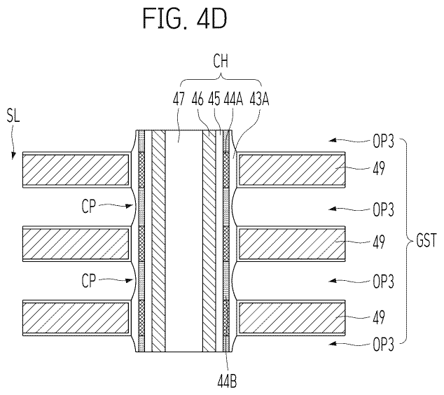

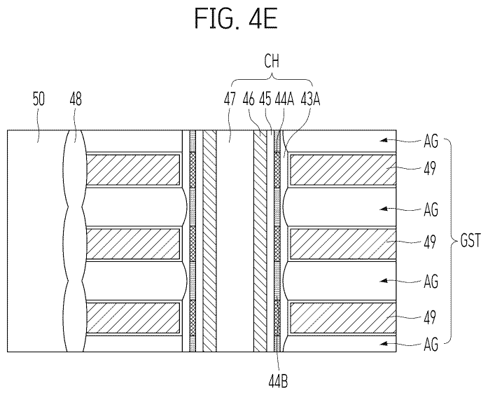

FIGS. 4A to 4E are diagrams for describing a manufacturing method of a semiconductor device in accordance with an embodiment of the present disclosure. Hereinafter, any description made earlier may not be repeated.

Referring to FIG. 4A, a stack ST including first material layers 41 and second material layers 42 that are alternately stacked may be formed. The first material layers 41 may each include a material having a high etching selectivity with respect to the second material layers 42. The first material layers 41 may be used to form gate lines. For example, the first material layers 41 may each include a sacrificial material such as nitride or a conductive material such as polysilicon or metal. The second material layers 42 may be used to form air gaps. For example, the second material layers 42 may each include a sacrificial material such as oxide.

Subsequently, a first opening OP1 extending through the stack ST may be formed, and a channel structure CH may be formed within the first opening OP1. The channel structure CH may include at least one of a blocking layer 43, a data storage layer 44, a tunneling layer 45, a channel layer 46, and an insulating core 47. For example, the blocking layer 43 may be formed conformally within the first opening OP1 on the sidewall surface of the first opening. The data storage layer 44 may then be formed conformally on the blocking layer 43 to cover the exposed sidewall surface of the blocking layer 43. Likewise, the tunneling layer 45 may then be formed conformally on the data storage layer 44 to cover the exposed sidewall of the data storage layer 44, and the channel layer 46 may be formed conformally on the tunneling layer 45 to cover the exposed sidewall surface of the tunneling layer 45. The insulating core 47 may be formed within the channel layer 46. A layer being formed conformally on another layer means that the newly formed layer follows the contours and topography of the underlying layer without leaving gaps or voids. This conformal deposition results in the formation of a uniform thickness layer and ensures proper performance of the semiconductor device.

The blocking layer 43 may include a material having a high etching selectivity with respect to the second material layers 42. For example, the second material layers 32 may each include an insulating material such as, for example, silicon oxide or silicon nitride, and the blocking layer 33 may include a high-k material such as, for example, hafnium oxide or aluminum oxide.

Referring to FIG. 4B, a slit SL may be formed to extend through the stack ST along the direction of the stacking. Subsequently, second openings OP2 may be formed by removing the first material layers 41 through the slit SL. Subsequently, third material layers 49 may be formed within the second openings OP2, respectively. For example, the third material layers 49 may be used to form gate lines. For example, a barrier layer 49A may be formed within the second opening OP2, and a metal layer 49B may be formed within the barrier layer 49A. Through this, a gate structure GST including the second material layers 42 and the third material layers 49 that are alternately stacked may be formed.

For reference, when the first material layers 41 each include the conductive material, a process of forming the third material layers 49 may be omitted. In such a case, the first material layers 41 may be used as the gate lines, and the stack ST may be used as the gate structure GST.

Referring to FIG. 4C, the second material layers 42 and the blocking layer 43 may be etched through the slit SL. For example, third openings OP3 exposing the blocking layer 43 may be formed by etching the second material layers 42 through the slit SL. In this case, an etching process may be performed under a condition in which an etching selectivity of the second material layers 42 with respect to the blocking layer 43 is high. For example, an etching selectivity between the blocking layer 43 and the second material layers 42 may be 100:1 to 500:1. Accordingly, in a process of etching the second material layers 42, the data storage layer 44 may be protected with the blocking layer 43.

When the second material layers 42 are etched under the condition in which the etching selectivity of the second material layers 42 with respect to the blocking layer 43 is high, the blocking layer 43 may be partially etched in the process of etching the second material layers 42. A surface of the blocking layer 43 exposed through the third openings OP3 may be partially etched deeply, and concave portions CP may be formed on the surface of the blocking layer 43. Each of the concave portions CP may have a surface with a round shape. Accordingly, a blocking layer 43A including the concave portions CP may be formed without performing a separate etching process of etching the blocking layer 43.

Referring to FIG. 4D, the data storage layer 44 may be oxidized through the concave portions CP of the blocking layer 43A. For example, the data storage layer 44 may be oxidized using a thermal oxidation process or a plasma oxidation process. Through the oxidation process, the data storage layer 44 may be partially oxidized and be separated into data storage patterns 44A. Portions of the data storage layer 44 which are adjacent to the concave portions CP (i.e., those portions which correspond to the concave portions CP) are oxidized, and form the oxidation patterns 44B. The portions of the data storage layer 44 which are next to the third material layers 49 are not oxidized. The portions of the data storage layer 44 which remain without being oxidized become the data storage patterns 44A. Each pair of consecutive data storage patterns 44A is thus separated from each other by an oxidation pattern 44B.

Because the data storage layer 44 is oxidized through the concave portions CP, the data storage layer 44 may be uniformly oxidized. When the oxidation process is performed in a state in which the data storage layer 44 is exposed, oxidized degrees of the data storage layer 44 may be different from each other depending on a distance from the slit SL, and sizes and shapes of the data storage patterns 44A may be non-uniform. As the data storage layer 44 becomes closer to the slit, the data storage layer 44 may be more oxidized, and the size of the data storage pattern 44A may be smaller. Conversely, when the data storage layer 44 is oxidized in a state in which the blocking layer 43A is not etched at all, the data storage layer 44 might not be sufficiently oxidized, and the data storage patterns 44A might not be separated from each other. In addition, when an excessive oxidation process is performed in order to sufficiently oxidize the data storage layer 44, surrounding layers may be damaged. According to an embodiment of the present disclosure, the data storage layer 44 may be oxidized through the concave portions CP. Because the data storage layer 44 is oxidized through the concave portions CP having a relatively small thickness, the data storage layer 44 may be uniformly oxidized regardless of its location. In addition, the data storage layer 44 may be sufficiently oxidized so that the data storage patterns 44A are separated from each other.

Referring to FIG. 4E, a sealing layer 48 may be formed within the slit SL. The sealing layer 48 may be formed by depositing a sealing material in a manner in which step coverage is poor. For example, the sealing layer 48 may include carbon or oxide. The sealing material may be deposited on sidewalls of the third material layers 49 exposed through the slit SL, and may define air gaps AG by sealing the third openings OP3. Depending on a deposition condition, a region where the sealing material is deposited may be adjusted. When the sealing material is deposited under the condition where the step coverage is poor, the sealing material might not be deposited or may be minimally deposited, inside the third openings OP3. Through this, sizes of the air gaps AG may be increased.

Subsequently, a source contact structure 50 may be formed within the slit SL. The source contact structure 50 may include a conductive material such as, for example, polysilicon, tungsten, or molybdenum. For reference, it is also possible to form a gap fill layer instead of the source contact structure 50, and the gap fill layer may include an insulating material, a semiconductor material, or the like.

According to the manufacturing method described above, the blocking layer 43A including concave portions CP may be formed, and the data storage layer 44 may be partially oxidized through the concave portions CP. Through this, the data storage layer 44 may be separated into the data storage patterns 44A, and data retention characteristics may be improved.

Because the air gaps AG are formed between the stacked third material layers 49, capacitance between the stacked third material layers 49 may be reduced. In addition, because the blocking layer 43A includes the concave portions CP, capacitance between the third material layer 49 and the channel layer 46 may be reduced.

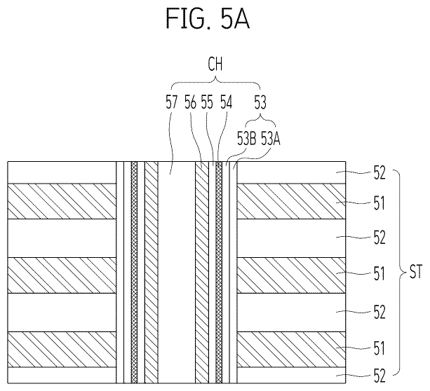

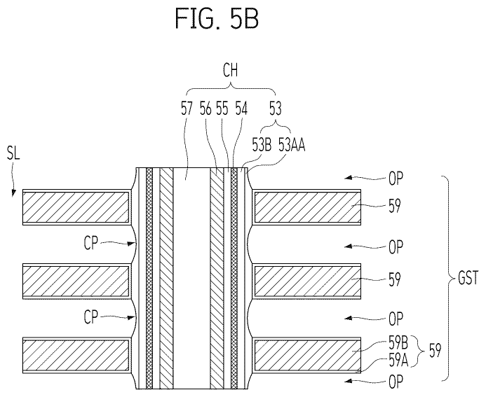

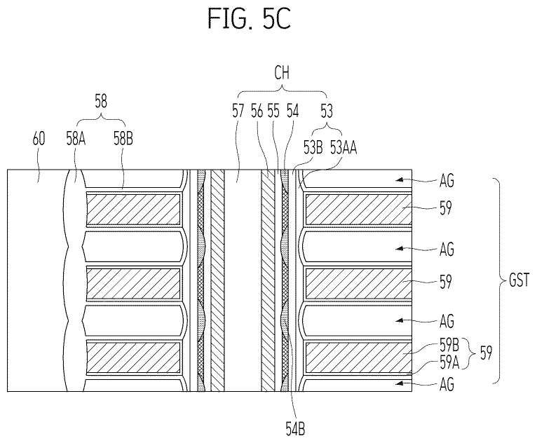

FIGS. 5A to 5C are diagrams for describing a manufacturing method of a semiconductor device in accordance with an embodiment of the present disclosure. Hereinafter, any description made earlier may not be repeated.

Referring to FIG. 5A, a stack ST is formed to include first and second material layers 51 and 52 that are alternately stacked. Subsequently, a channel structure CH extending through the stack ST in the stacking direction is formed and may include at least one of a blocking layer 53, a data storage layer 54, a tunneling layer 55, a channel layer 56, and an insulating core 57. In this embodiment, the blocking layer 53 includes a first blocking layer 53A and a second blocking layer 53B.

The first and second blocking layers 53A and 53B may include materials having different dielectric constants. For example, the first blocking layer 53A may include a material having a higher dielectric constant than the second blocking layer 53B. The first blocking layer 53A may include a high-k material such as, for example, hafnium oxide or aluminum oxide, and the second blocking layer 53B may include a low-k material such as, for example, silicon oxide or silicon nitride.

Referring to FIG. 5B, a slit SL may be formed to extend through the stack ST along the stacking direction. Then, the first material layers 51 may be replaced with third material layers 59 through the slit SL. For example, the third material layers 59 may be used to form gate lines. For example, a metal layer 59B may be formed after a barrier layer 59A is formed. Through this, a gate structure GST including the second material layers 52 and the third material layers 59 that are alternately stacked may be formed.

Subsequently, the second material layers 52 and the blocking layer 53 may be etched through the slit SL. For example, openings OP exposing the first blocking layer 53A may be formed by etching the second material layers 52 through the slit SL. In this case, an etching process may be performed under a condition in which an etching selectivity of the second material layers 52 with respect to the first blocking layer 53A is high. For example, an etching selectivity between the first blocking layer 53A and the second material layers 52 may be 100:1 to 500:1. Accordingly, in a process of etching the second material layers 52, the second blocking layer 53B and the data storage layer 54 may be protected with the first blocking layer 53A.

In the process of etching the second material layers 52, the first blocking layer 53A may be partially etched. A surface of the first blocking layer 53A exposed through the openings OP may be partially etched deeply, and concave portions CP may be formed on the surface of the first blocking layer 53A. Through this, a first blocking layer 53AA including the concave portions CP may be formed. The first blocking layer 53AA may have a continuously connected shape.

Depending on an etching condition, the first blocking layer 53A may be etched to expose the second blocking layer 53B. In such a case, the second blocking layer 53B may be partially etched, and concave portions CP may be formed on a surface of the second blocking layer 53B.

Referring to FIG. 5C, the data storage layer 54 may be oxidized through the concave portions CP of the blocking layer 53. The data storage layer 54 may be oxidized through the first blocking layer 53A and the second blocking layer 53B or oxidized through the second blocking layer 53B. Through this, data storage patterns 54A and oxidation patterns 54B may be formed. For reference, when the data storage layer 54 is oxidized through the first blocking layer 53A and the second blocking layer 53B, the second blocking layer 53B may be formed to have a thickness of 5 nm or less so that the data storage layer 54 is sufficiently oxidized.

Subsequently, a sealing layer 58 may be formed within the slit SL. The sealing layer 58 may be formed by depositing a sealing material in the slit SL. In this case, the sealing material may also be deposited within the openings OP. A thickness at which the sealing material is deposited may be adjusted through adjustment of a deposition recipe considering the step coverage. Through this, the sealing layer 58 including a penetration portion 58A and extension portions 58B may be formed. A portion formed within the slit SL may be the penetration portion 58A, and portions formed within the openings OP may be the extension portions 58B. Subsequently, a source contact structure 60 or a gap fill layer may be formed within the slit SL.

According to the manufacturing method described above, the blocking layer 53 may be formed as a multilayer layer. By forming the blocking layer 53 as the multilayer layer, it is possible to improve an increase in leakage current while reducing capacitance. In addition, by forming the extension portions 58B within the openings OP, it is possible to compensate for a decrease in electric field strength due to the air gaps AG.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure. Furthermore, the embodiments may be combined to form additional embodiments.

What is claimed is:

1. A semiconductor device comprising:
a gate structure including stacked conductive layers and insulating regions disposed between the conductive layers;
a channel layer extending through the gate structure;
data storage patterns surrounding the channel layer and disposed between the channel layer and the conductive layers, respectively;
oxidation patterns surrounding the channel layer and disposed between the channel layer and the insulating regions, respectively; and
a blocking layer surrounding the data storage patterns and the oxidation patterns and including concave portions disposed to correspond to the insulating regions.

2. The semiconductor device of claim 1, wherein each of the insulating regions includes an air gap.

3. The semiconductor device of claim 1, wherein the blocking layer includes first portions surrounding the data storage patterns and second portions surrounding the oxidation patterns, and the second portion has a smaller thickness than the first portion.

4. The semiconductor device of claim 1, wherein the concave portions are disposed on an outer wall of the blocking layer.

5. The semiconductor device of claim 1, wherein each of the concave portions has a surface with a round shape.

6. The semiconductor device of claim 1, wherein each of the concave portions includes a center and an edge, and the blocking layer has a smaller thickness at the center than at the edge.

7. The semiconductor device of claim 1, wherein sidewalls of the data storage patterns facing the oxidation patterns include curved surfaces.

8. The semiconductor device of claim 1, further comprising:
a source contact structure extending through the gate structure; and
a sealing layer surrounding a sidewall of the source contact structure.

9. The semiconductor device of claim 8, wherein the sealing layer includes grooves disposed to correspond to the insulating regions.

10. The semiconductor device of claim 8, wherein the sealing layer includes first portions disposed between the conductive layers and the source contact structure and second portions disposed between the insulating regions and the source contact structure, and the second portion has a smaller thickness than the first portion.

11. The semiconductor device of claim 8, wherein the sealing layer comprises:
a penetration portion extending through the gate structure; and
extension portions extending into the gate structure along surfaces of the conductive layers.

12. The semiconductor device of claim 11, wherein the extension portions extend along the concave portions of the blocking layer.

13. The semiconductor device of claim 11, wherein the insulating regions are disposed within the extension portions.

14. The semiconductor device of claim 1, wherein the blocking layer includes a high-k material.

15. The semiconductor device of claim 1, wherein the blocking layer comprises:
a first blocking layer including the concave portions; and
a second blocking layer disposed between the data storage patterns and the first blocking layer and between the oxidation patterns and the first blocking layer.

16. The semiconductor device of claim 15, wherein the first blocking layer includes a high-k material, and the second blocking layer includes a low-k material.

17. A semiconductor device comprising:
a gate structure including stacked gate lines;
a channel layer extending through the gate structure;
a tunneling structure surrounding the channel layer and including protrusion portions disposed between the gate lines;
data storage patterns surrounding the tunneling structure and disposed between the protrusion portions, respectively;
a blocking layer surrounding the data storage patterns and the tunneling structure; and
a sealing layer extending through the gate structure and defining air gaps disposed between the gate lines,
wherein each of the air gaps protrudes into the blocking layer and the sealing layer.

18. The semiconductor device of claim 17, wherein the tunneling structure comprises:
a tunneling layer surrounding a sidewall of the channel layer; and
oxidation patterns surrounding the tunneling layer and disposed between the data storage patterns, respectively.

19. The semiconductor device of claim 17, wherein the blocking layer comprises:
a second blocking layer surrounding the data storage patterns and the tunneling structure; and
a first blocking layer surrounding the second blocking layer and including concave portions.

20. The semiconductor device of claim 17, wherein the sealing layer comprises:
a penetration portion extending through the gate structure; and
extension portions extending into the gate structure along surfaces of the gate lines.

21. A manufacturing method of a semiconductor device, the manufacturing method comprising:
forming a stack including first material layers and second material layers that are alternately stacked;
forming a first opening extending through the stack;
forming a blocking layer within the first opening;
forming a data storage layer within the blocking layer;
forming a slit extending through the stack;
forming second openings by etching the second material layers through the slit, the second openings exposing the blocking layer;
forming concave portions on a surface of the blocking layer by etching the blocking layer exposed through the second openings; and
oxidizing the data storage layer through the concave portions of the blocking layer.

22. The manufacturing method of claim 21, wherein the data storage layer is protected by the blocking layer when the second openings are formed.

23. The manufacturing method of claim 21, wherein in a process of etching the second material layers, the blocking layer is partially etched to form the concave portions.

24. The manufacturing method of claim 21, wherein the blocking layer includes a material having a high etching selectivity with respect to the second material layers.

25. The manufacturing method of claim 21, wherein the blocking layer includes a material having a higher dielectric constant than the second material layers.

26. The manufacturing method of claim 21, wherein each of the concave portions has a surface with a round shape.

27. The manufacturing method of claim 21, wherein in the oxidizing of the data storage layer, the data storage layer is partially oxidized and separated into data storage patterns.

28. The manufacturing method of claim 21, wherein forming the blocking layer comprises:
forming a first blocking layer within the first opening;
forming a second blocking layer within the first blocking layer, and
wherein the data storage layer is oxidized through the second blocking layer.

29. The manufacturing method of claim 28, wherein the first blocking layer includes a high-k material, and the second blocking layer includes a low-k material.

30. The manufacturing method of claim 21, further comprising:
forming a tunneling layer within the data storage layer; and
forming a channel layer within the tunneling layer.

31. The manufacturing method of claim 21, further comprising replacing the first material layers with third material layers through the slit.

32. The manufacturing method of claim 21, further comprising forming a sealing layer within the slit to define air gaps within the second openings.

33. The manufacturing method of claim 32, further comprising forming a source contact structure within the slit.
